(19) United States
(12) Patent Application Publication
(10) Pub. No.: US 2026/0093855 A1
(43) Pub. Date: Apr. 2, 2026

(54) GENERATION AND MODIFICATION OF MODEL-BASED DEFINITION ELEMENTS WITHIN DRAWING GRAPHICS SHEET OF A COMPUTER-AIDED DRAFTING ENVIRONMENT

(71) Applicant: Dassault Systemes SolidWorks Corporation, Waltham, MA (US)

(72) Inventors: Matthew Lorono, Broomfield, CO (US); Raghavendra Vhanbatte, Pune (IN)

(21) Appl. No.: 18/901,617

(22) Filed: Sep. 30, 2024

(51) Int. Cl. G06F 30/12

(52) U.S. Cl. CPC G06F 30/12

(57) ABSTRACT

A computer-based method is disclosed that includes displaying a two-dimensional view of an object on a sheet on a graphical user interface of a two-dimensional drawing environment in a computer-aided drafting (CAD) application. The CAD application is configured to provide access to the two-dimensional drawing environment and a three-dimensional model-based definition environment. The method includes receiving a user-provided annotation attached to a selected geometry on the displayed object in the two-dimensional drawing environment. A two-dimensional view inverse transformation is applied to the annotation attached to the selected geometry to produce a transformed version of the annotation. The transformed version of the annotation is attached to a corresponding geometry in a three-dimensional version of the object in the three-dimensional model-based definition environment.

### FIELD OF THE INVENTION

This disclosure relates to the field of computer-implemented design and modeling, and more particularly, relates to the generation and modification of model-based definition (MBD) elements within a drawing graphics sheet of a computer-aided drafting (e.g., design) environment.

### BACKGROUND

There has been a barrier to adopting model-based definition and model-based enterprise in product design. This barrier has been based, at least in part, by users' desires to utilize engineering drawings to communicate product definition for design review, product manufacturing, incoming inspection, etc. With interconnectivity and the ability to reuse information digitally, the use of engineering drawings for this purpose is becoming increasingly cumbersome. However, some personnel may still expect and want to rely on engineering drawings for these and other purposes.

### SUMMARY OF THE INVENTION

In one aspect, a computer-based method is disclosed for generating and/or modifying drawings, views, and/or annotations for a model-based definition (MBD) environment in a drawing graphics sheet in a computer-aided drafting environment. The computer-based method includes displaying a two-dimensional view of an object on a sheet on a graphical user interface of a two-dimensional drawing environment in a computer-aided drafting (CAD) application. The CAD application is configured to provide access to the two-dimensional drawing environment and a three-dimensional model-based definition environment. The method includes receiving a user-provided annotation attached to a selected geometry on the displayed object in the two-dimensional drawing environment. A two-dimensional view inverse transformation is applied to the annotation attached to the selected geometry to produce a transformed version of the annotation. The transformed version of the annotation is attached to a corresponding geometry in a three-dimensional version of the object in the three-dimensional model-based definition environment.

In another aspect, a system is disclosed that includes a computer with a computer processor, and computer-based memory operatively coupled to the computer processor. The computer-based memory stores computer-readable instructions that, when executed by the computer processor, cause the computer system to generate and/or modify drawings, views, and/or annotations for a model-based definition (MBD) environment in a drawing graphics sheet in a computer-aided drafting environment in accordance with a method that includes displaying a two-dimensional view of an object on a sheet on a graphical user interface of a two-dimensional drawing environment in a computer-aided drafting (CAD) application. The CAD application is configured to provide access to the two-dimensional drawing environment and a three-dimensional model-based definition environment. The method includes receiving a user-provided annotation attached to a selected geometry on the displayed object in the two-dimensional drawing environment. A two-dimensional view inverse transformation is applied to the annotation attached to the selected geometry to produce a transformed version of the annotation. The transformed version of the annotation is attached to a corresponding geometry in a three-dimensional version of the object in the three-dimensional model-based definition environment.

In yet another aspect, a non-transitory computer readable medium is disclosed that has stored thereon computer-readable instructions that, when executed by a computer-based processor, cause the computer-based processor to generating and/or modifying drawings, views, and/or annotations for a model-based definition (MBD) environment in a drawing graphics sheet in a computer-aided drafting environment via a method that includes displaying a two-dimensional view of an object on a sheet on a graphical user interface of a two-dimensional drawing environment in a computer-aided drafting (CAD) application. The CAD application is configured to provide access to the two-dimensional drawing environment and a three-dimensional model-based definition environment. The method includes receiving a user-provided annotation attached to a selected geometry on the displayed object in the two-dimensional drawing environment. A two-dimensional view inverse transformation is applied to the annotation attached to the selected geometry to produce a transformed version of the annotation. The transformed version of the annotation is attached to a corresponding geometry in a three-dimensional version of the object in the three-dimensional model-based definition environment.

In still another aspect, there is provided a computer program product configured to be operable to generate and/or modify drawings, views, and/or annotations for a model-based definition (MBD) environment in a drawing graphics sheet in a computer-aided drafting environment, in accordance with a method that includes displaying a two-dimensional view of an object on a sheet on a graphical user interface of a two-dimensional drawing environment in a computer-aided drafting (CAD) application. The CAD application is configured to provide access to the two-dimensional drawing environment and a three-dimensional model-based definition environment. The method includes receiving a user-provided annotation attached to a selected geometry on the displayed object in the two-dimensional drawing environment. A two-dimensional view inverse transformation is applied to the annotation attached to the selected geometry to produce a transformed version of the annotation. The transformed version of the annotation is attached to a corresponding geometry in a three-dimensional version of the object in the three-dimensional model-based definition environment.

In some implementations, one or more of the following advantages are present.

In some implementations, for example, the systems and techniques disclosed herein facilitate the transitional use of engineering drawings, and/or even the ability to make both engineering drawings and model-based definition (MBD) documents available for different information consumers or situations. In various implementations, the systems and techniques disclosed herein help users overcome challenges in transitioning from drawings-based processes to MBD. More specifically, in various implementations, the systems and techniques disclosed herein provide for changes to engineering workflows to cater to the needs of various personnel desiring or demanding either or both of 2D and 3D definition. In various implementations, the systems and techniques disclosed herein facilitate processes of product definition and mechanical drafting, for example, as well as adjoining workflows into areas of quality assurance and product manufacturing.

In some implementations, the systems and techniques disclosed herein may be implemented on the 3DEXPERIENCE® platform, available from Dassault Systèmes Solidworks Corporation, the applicant of the current application. More specifically, the systems and techniques disclosed herein may be integrated into the Manufacturing Definition Creator role in the xDrawing™ or xDesign™ computer application on the 3DEXPERIENCE® platform.

Within an appropriately adapted version of the xDrawing™ app, MBD may be created, stored, visualized, edited and otherwise accessed within a 3D model environment that enables product definition to be applied and used in the three spatial dimensions as represented on a computer screen, called “an MBD environment.” Additionally, drawing-based product definition may be created, stored, visualized, edited and otherwise accessed within a 2D drawing graphics sheet environment as represented on a computer screen, called “a drawing environment.” Presentation states and saved views (as defined and used, for example, by ASME Y14.3, ASME Y14.41 and ASME Y14.47, and counterpart ISO standards) may be employed to organize annotations and visual representation within the MBD environment in a form called “MBD Views.” Moreover, representation of the MBD Views may be shown within the drawing environment in the form of traditional drawing views. Notably, implementations that include the systems and techniques disclosed herein, facilitate the creation of drawing views from existing MBD Views, and annotations may be created in the MBD environment or in the drawing environment.

In some such implementations, the systems and techniques disclosed herein may provide robust support to and seamless integration of both MBD and engineering drawing functionalities. Manufacturing Definition Creator™ is a browser-based solution that runs on the 3DEXPERIENCE® platform. In an exemplary implementation, Manufacturing Definition Creator™ is adapted, as described herein, to combine model-based (e.g., MBD) and drawing-based capabilities in one integrated solution. With such a solution, a user may easily define parts and assemblies with either traditional engineering drawings or model-based definition workflows simply, straightforwardly, and conveniently. The combination of these (2D and 3D) definition capabilities may provide a high degree of flexibility, empowering users to choose, for example, the best output for each job to effectively meet stakeholders' needs. In such implementations, users can define model-based product manufacturing information (PMI) (e.g., dimensions, tolerances, datum symbols, geometric dimensioning and tolerances, balloons, surface finish symbols, note, tables and more) directly on a model. The user can easily organize annotations into specific views to communicate and paint a visual story of project requirements, for example, with intuitive cross highlighting meaning highlight associated geometry of the part with annotations. Moreover, in a typical implementation, users are able to easily create drawings from model definitions to meet, for example, personal needs as well as the needs of suppliers, customers, and others.

In various implementations, (e.g., with an adapted version of Manufacturing Definition Creator), a user does not always have to create drawings from scratch. In such instances, the xDrawing™ application, for example, may provide a single source of truth that allows users to utilize PMI across different forms of definition, including MBD and in engineering drawings, and to easily eliminate discrepancies therebetween. Drawing creation, in such implementations, can be accomplished generally with just a few mouse clicks. No rework, extra documents, or excessive effort is typically required. Existing model views, for example, can simply be placed on a sheet, and a user is ready to go to produce any desired engineering drawings, with associated annotations. Whether on the model or on the drawing: the views, annotations, dimensions, and tolerances are always up-to-date and synchronized.

In a typical implementation, the systems and techniques disclosed herein save time, effort and money; reworking or recreating drawing for something already defined can be avoided. Moreover, sharing information across multiple users may be facilitated, particularly when implemented on a platform such as the 3DEXPERIENCE® platform. Users can easily communicate manufacturing definition using annotated models and/or drawings with internal or external stakeholders in standard industry formats, like PDF, DXF, DWG and/or STEP 242.

Implementations of the systems and techniques disclosed herein provide a single source of truth with a streamlined connection between design, manufacturing and/or other associated functionalities. It facilitates an intuitive 3D approach to product definition for establishing and communicating design requirements and reduces discrepancies in associated 2D drawings, and vice versa.

Implementations of the systems and techniques disclosed herein enable users to define parts and assemblies directly from a drawings environment or from an MBD environment, enabling users to choose which methodology works best for them. In various implementations, a user can add views, dimensions and tolerances, notes and/or more, directly within the drawings environment. Typically, anything created on a drawing is automatically and simultaneously generated on the corresponding model in the background, saving time and preserving a single source of truth for all information relating to an object represented in a drawing and/or a corresponding model.

Certain implementations facilitate MBD View creation via drawing environment. For example, one can create a 2D drawing view. In response, the computer automatically creates a corresponding view in MBD. All the associated data, including, for example, any annotation data, may be transferred over automatically. Additionally, an implementation of the systems and techniques disclosed herein may provide the ability to create and modify MBD Views from the drawing environment (e.g., by initiating and using a tool that creates drawing views). Initiating the drawing view tool, in some instances, provides the user with a list of standard and non-standard orientations relative to the modelled product/object. In various implementations, preview generation for possible drawing views may be created using one of two methods. In the first method, the software may generate a temporary preview for each of the offered orientations as possible drawing views to be created, made available to the user for selection based on the preview, either in bulk or individually. In the second method, the software may generate a temporary preview for each of the user selected view orientations upon selection of that orientation by the user. With either method, typically, the underlying MBD View will be generated to create the temporary preview. The preview may show a visual representation of the MBD view on the drawing graphics sheet. For orientations with such previews generated, if the user does not select or unselects the previewed orientation, the associated MBD View may be stored for future use or discarded. Variations are possible.

In certain implementations, once the selection of view orientations is complete, and upon acceptance of that selection by the user, the software may place the previewed orientation on the drawing graphics sheet as a drawing view, either at a predetermined location or at a user selected location. The drawing view, an instance of the associated MBD View, may be displayed in a manner as to appear as a two-dimensional representation. Variations are possible.

In some implementations, changes made to an MBD View visual appearance (such as orientation, hide/show condition of geometry and any other visual condition), may be applied to both the MBD View and its associated drawing view immediately and virtually simultaneously. These changes may be initiated by the user from either the drawing environment or the MBD environment. The drawing views typically are not generative in nature. Instead, they are typically a direct view of an instance of the MBD View (of the 3D model itself). Variations are possible.

Various implementations provide for annotation creation and/or modification via the drawing environment. Within the drawing environment, in a typical implementation, the user may be able to initiate a tool that creates an annotation that attaches to geometry of the model, such as Dimension, Geometric Tolerance, Datum, Datum Target, Notes, Surface Finish Symbol, General Table, Bill of Material and Balloon. The user may then be able to select an element on the drawing graphics sheet that is associated with a drawing view, such as the drawing view border or model edge. The computer may then detect the selection and find the capture instance of the MBD View being targeted by the user selection. From the capture instance, the computer may then get the parent as a Capture Reference. This, in a typical implementation, allows focus to be applied on the selected capture instance as the current capture (the MBD View being edited) within the AnnotationSet. Once a current capture is established, the user may apply new annotations as product definition to the 3D model as it appears within the drawing environment on the drawings graphic sheet.

In some implementations, selection of geometry within a current capture may initiate the preview of an annotation per current conventions. See the flowchart from start to first use of step E for process of identification of the active MBD View and spatial alignment and other characteristics of the annotation in the correct orientation within that MBD View as it appears in the drawing environment and in the MBD environment on the correct annotation plane. Once a preview of the annotation is generated, the user may be able to drag the previewed annotation along the annotation plane in a manner that is aligned with the static view orientation of the drawing environment. The process may then continue in the flowchart to the second instance of Step E. Once the user selects the final position for the annotation, the process may continue to follow flowchart through Step B. Once an annotation is placed, it may appear in the exact same location and orientation within the drawing view and the MBD View in relation to the geometry and the common coordinate system of the 3D model, as established by the annotation plane upon which the annotation is placed.

At any time while no tool is active within the drawing environment, the user may hover mouse cursor over an annotation (or touch equivalent) to preselect an annotation. During such a hover, the annotation and its associated geometry may be highlighted, for example, with a preestablished color or other visual indication. See Step C on the flowchart. At any time while no tool is active, or while a tool is active that allows for the selection of annotations, allow the user to select an annotation (or touch equivalent). When an annotation is selected, the annotation and its associated geometry shall highlight with selection color or other indication. See Step C on the flowchart.

While in the drawing environment, the user, in an exemplary implementation, is able to select an annotation and drag it to a new location along an annotation plane (aligned to the view orientation of the drawing environment). Any change in location of the annotation within the drawing environment typically simultaneously is applied as the same change within the MBD environment for that same annotation. While in the MBD environment, the user, in an exemplary implementation, is able to select an annotation and drag it to a new location along its annotation plane. Any change to the location of the annotation within the MBD environment typically is applied simultaneously to that annotation within the drawing environment in all instances where that annotation appears. It is note that multiple drawing views may be created for one MBD View and displayed on one or several drawing graphics sheet within the drawing environment. It is also permissible to have an AnnotationSet that contains no drawing graphic sheets, or one that has drawing graphics sheets where some or none of the MBD Views have corresponding drawing views. However, in a typical implementation, all drawing views that appear in the drawing environment of an AnnotationSet have an associated MBD View.

Other features and advantages will be apparent from the description and drawings, and from the claims.

### BRIEF DESCRIPTION OF THE DRAWINGS

FIG. 1 is a schematic representation of an example of a system configured to implement certain functionalities disclosed herein.

FIGS. 2A-2H is a flowchart of exemplary processes that may be performed, individually or sequentially, by or with the computer in the system of FIG. 1 to facilitate the generation and/or modification of drawings, views, and/or annotations for a model-based definition (MBD) environment in a drawing graphics sheet in a computer-aided drafting environment.

Like reference characters refer to like elements.

### DETAILED DESCRIPTION

This document uses a variety of terminology to describe its inventive concepts. The terminology should be given its ordinary meaning and, unless otherwise indicated, may be understood as having meanings that are consistent with what follows.

For example, computer-aided design (CAD) software is computer software that allows a user to construct and manipulate complex three-dimensional (3D) models. SOLIDWORKS® computer software and CATIA® computer software, both of which are available from Dassault Systèmes SolidWorks Corporation, the applicant of the current application, are examples of CAD software that may be used, for example, to construct and manipulate complex three-dimensional (3D) models within a CAD environment. A “design engineer” is a typical user of a 3D CAD system. The design engineer typically designs physical and aesthetic aspects of 3D models and may be skilled in 3D modeling techniques. The design engineer typically creates parts and may assemble certain parts into a subassembly. A subassembly may also consist of other subassemblies. An assembly may be designed using parts and subassemblies. Parts and subassemblies may be collectively referred to as components. The phrase “design engineer” used herein should be construed broadly to include any one or more human users of a computer or computer system implementing the techniques disclosed herein.

A dimensioning tool is a computer software component that enables users to define, organize, and publish 3D product and manufacturing information (PMI), including dimensional and tolerance information for 3D model data in industry standard file formats for model based definition (MBD). An existing example of a dimensioning tool is the DimXpert™ tool, which is built into SOLIDWORKS® and enables users quickly and easily dimension models in 3D space. The DimXpert™ tool allows us to communicate sizes, locations, and tolerances so that other users can easily understand and manufacture our parts. More specifically, the DimXpert™ tool facilitates the application of datum, dimensions, tolerancing, and GD&T information directly into a 3D CAD model. DimXpert for parts is a set of tools that enable users to apply dimensions and tolerances to parts according to the requirements of ASME Y14.41-2003 and ISO 16792:2006. DimXpert tools allows users to insert dimensions and/or tolerances manually or automatically (e.g., from a database).

A sketching tool is a computer software component that enables users to produce 2D images (sketches) that can form the basis for a 3D model. Sketches can be created on any one or more planes including, for example, a front plane, a top plane, a right plane, or a created plane. The SOLIDWORKS® software programs includes a sketching tool that enables users to perform these functionalities. Sketching in SOLIDWORKS® is the basis for creating features. Features are the basis for creating parts, which can be put together into assemblies. In the SOLIDWORKS® software program, a user may create and/or edit sketches using, for example, sketch entities or a sketch tool, planes, or extruded or revolved bosses/bases. Users may add dimensions to sketches. However, features can be created from sketches with or without dimensions.

Drawing-based product definition may be created, stored, visualized, edited and otherwise accessed within a 2D drawing graphics sheet environment as represented on a computer screen, called “drawing environment.” A drawing environment may be considered distinct from a 3D modelling environment.

A “capture” may be considered a view, from a particular perspective or point of view of a part (and may or may not include annotations) in a CAD environment. A capture may help to describe and define, for example, the tolerancing of the product. A “capture instance” is one specific example of a capture of a particular product design. Multiple capture instances may be created based on one particular product design and/or one particular view of the product design. In an exemplary implementation, a capture instance includes a model, a capture border surrounding the model, and all annotations for the model.

The phrase “model rep” refers to a representation of a 3D model (e.g., in a CAD environment).

The phrase “bounding box” (shortened to “BB”) refers to a box (typically an imaginary or virtual rectangular box) that surrounds a 3D object or group of objects (e.g., in a virtual CAD environment). A bounding box may be used to define the outermost extents or limits of an object(s), providing a simple geometric representation of the object's (or objects') overall size and position. A minimum bounding box, for example, is a type of bounding box having the smallest possible measure (e.g., internal volume, etc.) within which an entirety of the 3D object or group of objects lie.

An “added tolerance” is a margin or buffer space that may be provided, for example, around a 3D model in a virtual (e.g., CAD-based) environment that ensures the 3D model is fully visible even if it extends slightly beyond set boundaries. An added tolerance may be expressed, for example, in units of length, and stored in computer memory.

“Scenes” generally provide a visual backdrop for a model (e.g., in a virtual, CAD-based environment). A “scene graph” is a data structure that facilitates the arrangement of logical and/or spatial representation of a graphical scene. In an exemplary implementation, it is a collection of nodes in a graph (or tree structure). Typically, an operation performed on a group in a scene graph automatically propagates its effect to all of its members. “SceneGraphOverrideSet” class is useful to apply a set of temporary modifications on graphical node occurrences. The following attributes may be overridden: Color, Opacity, Full material, Placement matrix, Visibility (show/no show), Pickability.

A “CSI selection object” is a selection object created by CSI (Compute Server Infrastructure) which contains data about a 3D model, such as geometries (e.g., faces, edges, and/or points).

A “pathElement” is a selection element that identifies where it a particular item is present in a 3D model representation. Every geometry/element/feature created has a unique traceable path in the model which can be used to find and access it and which is known as a pathElement. Also, it is a runtime object representing a path (e.g., in the form of tree, which the system disclosed herein may traverse in model data to find an associated element).

A “sheet” refers to a single page or piece of paper on which a drawing or set of drawings is or can be created or printed, or a virtual (e.g., CAD-based) representation of such a page or piece of paper.

“AnnotationSet” refers to a document that gathers captures, views, and/or texts that facilitates annotation tolerancing. In a typical implementation, an annotation set is a root object and a product life cycle reference. It may aggregate information (in some implementations, all information) needed to perform 3D annotation tolerancing (e.g., texts, captures, views). It typically points (e.g., via a first connection) to the annotated product. In the SOLIDWORKS computer program, for example, AnnotationSet is a container for technological and geometrical object (project) specifications defined, for example, using Functional Tolerancing & Annotation features. AnnotationSet may be stored as a Product Lifecycle Management (PLM) object within Dassault Systemes' 3DEXPERIENCE® Platform as a cloud-based dataset (as opposed to a dataset stored as a file within a Microsoft Windows® or iOS® operating systems). The xDrawing™ app, from Dassault Systemes, for example, has the ability to create both model-based product definition (usually known as “model-based definition” or “MBD” as an abbreviation) and drawing-based product definition and save it all within a single document—e.g., AnnotationSet. AnnotationSet, as described herein, serves as a single source of truth for annotations, views (and potentially other information) for drawings (e.g., in a 2D drawings environment) and models (e.g., in a 3D MBD environment) of a particular CAD representation of a real world object. Moreover, as described herein, a computer, in a typical implementation, may utilize the AnnotationSet to update either an MBD model or a drawing in view of changes to the other. In a typical implementation, these changes are made simultaneously (i.e., without the introduction of any deliberate delay) in both environments. The AnnotationSet, therefore, is able to and typically does serve as a single source of truth for generating and/or displaying either 2D engineering drawings or 3D MBD representations, each of which may include annotation data.

TPS refers to “Technological Product Specifications.” A TPS domain may be described using TPS objects (representing tolerancing sets, TPS Features, and Technologically and Topologically Related Surfaces, for example), and/or interfaces.

“Scaling” refers to a process of changing the size of an object or a geometric figure while preserving its shape. Scaling can occur in one or more dimensions, resulting in an enlargement or reduction of the object, along one or more dimensions.

Model based definition (MBD) refers to the practice of using 3D models, for example, within a 3D CAD software environment to define (provide specifications for) individual components, product assemblies, or the like. The types of information included may include geometric dimensioning and tolerancing (GD&T), component level materials, assembly level bills of materials, engineering configurations, design intent, etc. By contrast, other methodologies have historically required accompanying use of 2D engineering drawings to provide such details. Some 3D CAD applications allow for inserting engineering information such as dimensions, GD&T, notes and other product details within a 3D digital data set for a component and/or assembly. MBD uses such capabilities to establish the 3D digital data set as the source of these specifications and design authority for the product. The 3D digital data set may contain enough information to manufacture and inspect the product without the need for engineering drawings, which traditionally include such information. In many instances, using this information from 3D digital data set (e.g., the solid model) allows for rapid prototyping of a product via various processes, such as 3D printing. In some instances, a manufacturer may be able to feed 3D digital data directly into one or more manufacturing devices, such as computer numerical control (CNC) machines, to manufacture the final product. SOLIDWORKS MBD™ is an example of a computer software program that gives users access to MBD. In a typical implementation, it helps users define, organize, and publish 3D PMI, including 3D model data, such a dimensions and tolerances, in industry standard file formats. Moreover, SOLIDWORKS MBD operates within the SOLIDWORKS environment with its own CommandManager, and supports native SOLIDWORKS 3D part and assembly data, such as configurations, constraints, and PMI.

“Model-based enterprise” (“MBE”) is a phrase used in manufacturing, for example, to describe a strategy where an annotated digital three-dimensional (3D) model of a product serves as the authoritative information source for all activities in that product's lifecycle.

“Engineering drawings” (sometimes referred to as mechanical drawings, detail drawings, blueprints, or technical drawings) are documents that provide for a standard form of communication used by engineers, architects, electricians, construction experts, and many other professionals, to communicate design concepts and design intent using standardized pictorial language comprised of lines, shapes, and symbols and sometimes other language. Engineering drawings typically provide detailed information about an object's geometry, dimensions, materials, and/or tolerances. Engineering drawings typically take the form of two-dimensional representations depicting an object from one or more views such as a front view, a rear view, a top view, a bottom view, side views, etc. Sometimes additional views are provided, such as sectional, crop, or break views, crop views, break views, etc.). The information in an engineering drawing may be used to develop and/or refine designs, develop prototypes, and construct and maintain objects. As described herein, engineering drawings may also include annotation information about objects represented therein.

The phrase “processor” (or the like refers) to any one or more computer-based processing devices. A computer-based processing device is a physical component (e.g., a CPU) that can perform computer functionalities by executing computer-readable instructions stored in memory. If there is more than one computer-based processing device or processor cores, they can be contained in a single physical device (e.g., in a single a computer or server) or distributed across multiple physical devices that may be located, for example, in more than one physical location or facility.

The phrase “memory” (or the like) refers to any one or more computer-based memory devices. A computer-based memory device is a physical component that can store computer-readable instructions that, when executed by a processor, results in the processor performing associated computer functionalities. If there is more than one computer-based memory device, they can be contained in a single physical device (e.g., a computer or server) or distributed across multiple physical devices that may be in more than one physical location or facility.

The phrase “computer numerical control” or “CNC” refers to the automatic control of one or more machining tools, such as lathes, drills, grinders, routers, mills, 3D printers, etc. by means of a computer. A “CNC machine” is a machine that includes one or more such machining tools and that is configured to process a piece of material (e.g., metal, plastic, ceramic, wood, composite, etc.) to meet specifications by following coded programmed instructions and without a manual operator directly controlling the machining operation. Instructions may be delivered to a CNC machine from a computer in the form of a sequential program of machine control instructions, and then executed by the CNC machine. In some instances, the program may have been generated by or from CAD software and/or computer-aided manufacturing (“CAM”) software (e.g., based on a model that was generated using the CAD/CAM software). In such instances, the object's mechanical dimensions, for example, may have been defined using the CAD software and then translated into manufacturing directives (e.g., by corresponding CAM software). The resulting directives may be utilized as (or to provide) CNC-compatible commands necessary for a particular CNC machine to perform manufacturing operations in connection with producing a real-world version of the object. The CNC-compatible commands may be loaded into and executed by the CNC machine to perform real-world manufacturing operations (e.g., subtractive operations) on one or more pieces of material (e.g., metal, plastic, ceramic, wood, composite, etc.).

A number of terms and phrases particular to CAD programs are used herein. Unless otherwise indicated, these terms and phrases should have meanings that correspond with the following. For example, the phrase “annotation” refers to a callout to convey product and manufacturing requirements and instructions, such as notes, datum symbols, geometric dimensions and tolerances, weld symbols, surface finishes, etc. An annotation can be attached to and associated with a 3D model, for example, or displayed separately from a 3D model, commonly referred to as a 3D annotation. A 3D annotation can be displayed graphically for human eye readings and can also represent semantic meanings beyond the graphical presentation. The phrase “assembly” refers to a document in which parts, features, and other assemblies (subassemblies) are mated together. Parts and subassemblies can exist in documents separate from the assembly. For example, in an assembly, a piston can be mated to other parts, such as a connecting rod or cylinder. This assembly can then be used as a subassembly in an assembly of an engine. The term “component,” when used in reference to a CAD design, refers to any part or subassembly within an assembly. The term “datum” refers to a theoretical exact plane, axis, or point location to which GD&T or dimensional tolerances, for example, reference. A “datum target” is a point, line, or limited zone (e.g., on a drawing or model) used to establish a datum. An “edge,” as used herein, refers to a single outside boundary of a feature. The term “entity” refers to a discrete element, such a face, edge, vertex, etc. The term “face” refers to a selectable area (planar or otherwise) of a model or surface with boundaries that help define the shape of the model or surface. For example, a rectangular solid has six faces, and a cylindrical solid has three faces. The term “feature” refers to an individual shape that, combined with other features, makes up a part or assembly. The term “part” refers to a single 3D object made up of features. A part can include multiple bodies. A part can become a component in an assembly. Examples of parts include, for example, a bolt, pin, and plate. The term “plane” refers to a flat construction geometry. The term “point” refers to a singular location in a 3D model or a sketch. The term “subassembly” refers to an assembly that is part of a larger assembly. For example, a steering mechanism of a car is a subassembly of the car. The term “surface” refers to a zero-thickness planar or 3D entity with edge boundaries. The term “vertex” refers to a point at which two or more edges intersect. Vertices can be selected for sketching, dimensioning, and many other CAD operations.

### Technical Disclosure

The concept of using a display of (or representative of) a 3D Model directly on a drawing graphics sheet for the purpose of providing product definition on an engineering drawing may be provided, for example, within 2D Layout for 3D, a CATIA product, or xDrawing™, a SOLIDWORKS product. 2D Layout for 3D Design is a product that enables users to design 3D models in an advanced 2D drafting-like production environment and enables users to create layout views based on 2D geometry. Once a design is laid out in 2D sheets and views, the user is able to print it directly or generate a drawing sheet from it, or to add views to illustrate it in other ways. A drawback to this approach is that the workflow for the generation of product definition is one directional only, driven by adding annotations on the 3D model within a modelling environment.

The more general concept of generating drawing views and inserting product definition annotations on a drawing graphics sheet from saved views, presentation states, and annotation views within 3D model environment may be provided in certain 3D CAD application environments. However, the workflow for generation of the product definition for MBD in such implementations is generally one directional, only driven by creating annotations on the 3D model within a modelling environment. Second, the views that appear on the drawing graphics sheet tend to be generative, meaning they are 2D machine interpretations of the 3D model (similar to a person looking at a physical item and then using a pencil to sketch a view of the item from a particular point of view onto a sheet of paper). Although, when annotations are added to these views on the drawing graphics sheet, in some instances, they can be linked back to the geometry of the 3D model. (See next paragraph).

The concept of creating product definition annotations on a drawing graphic sheet may be provided in various CAD applications. A drawback of this concept is that generally the annotations are not generally linked to annotations in the 3D modelling environment. The annotations only exist on the drawing graphics sheet. If the user wishes to create product definition annotations within the 3D modelling environment after creating them on the drawing graphics sheet, the user must recreate them separately. With no link between these annotations in the 3D modelling environment and those on drawing graphics sheet, the user must edit each instance separately, even for annotations that define the same element of the product.

For annotations created in a 3D modelling environment and shown on a drawing graphic sheet, the annotations may be linked back to the 3D model and to annotations within the 3D modelling environment. The user can edit these inserted annotations which appear on the drawing graphics sheet to change aspects of the model, to change the characteristics of the model, to change the value show in the annotations; and to change the location of annotations. As noted above, for this to work, the annotations must first be created in the 3D modelling environment. In such instances, editing may be bidirectional, but creation is one-directional only. Annotations created on the drawing graphics sheet can be linked to the geometry of the 3D model (e.g., so that they update when the 3D model changes), but they only exist on the drawing graphics sheet, with no presence in the 3D modelling environment, nor do they have effect on the 3D model when they are edited. The concept of generating product definition annotations in the 3D modelling environment from annotations on a drawing graphic sheet is generally a one-and-done operation to convert from drawing usage to an MBD system. There is generally no link between the annotations on the drawing graphic sheet and annotations on the 3D modelling environment thereafter.

In various implementations, the systems and techniques disclosed herein address and/or overcome one or more (or all) shortcomings of other approaches.

It is worth noting that, to date, there has been a major barrier to adopting Model-based definition (MBD) and Model-based enterprise (MBE) approaches. This barrier is based on the need/desire to provide engineering drawings to communicate product definition, for example, for design review, product manufacturing, and/or incoming inspection. With increasing interconnectivity and an increasing ability to reuse information digitally, the use of engineering drawings for this purpose is becoming increasingly cumbersome. However, many vendors and internal personnel still expect and rely on drawings. There is a need, therefore, to facilitate the transitional use of engineering drawings, or even to make both engineering drawings and MBD documents available and easy to utilize for providing information to various personnel. In various implementations, the systems and techniques disclosed herein solve these challenges by combining the effort of creating product definition without the need to manage separate documents or workflows. This cuts labor hours in creation, use and management of product definition documents by deploying a single-source-of-truth and supporting multiple workflows where the producer doesn't have to make a choice between drawings or MBD. In various implementations, the systems and techniques disclosed herein provide technical solutions to these, and potentially other, technical problems in a CAD software environment, particularly involving MBD and engineering drawings.

The systems and techniques disclosed herein provide for a single document, referred to herein as an AnnotationSet, stored in computer-based memory and that contains all annotation/product manufacturing information (e.g., dimensional information, geometric tolerances, datum, datum targets, notes, surface finishes, balloons, views, etc.) for an object represented in a model and/or any corresponding engineering drawings thereof. Any computer representation produced of the object, whether in an MBD environment or a drawings environment, is logically associated with the AnnotationSet, such that the annotation information contained therein is available to, and may be presented in, that computer representation. Any annotation information added to the object, whether in the MBD environment or in the drawings environment, is likewise saved in the AnnotationSet, such that the added information will be available to, and may be presented with, the computer representation of the object, to which the annotation information has been added and to any subsequent computer representations of that object, whether in the MBD environment or in the drawings environment, unless the annotation information subsequently changes or is deleted. Likewise, any edits to the annotation information for an object, whether made in the MBD environment or the drawings environment, is also saved in the AnnotationSet, such that the edited information will be available to, and may be presented with, the computer representation of the object that has been edited and to any subsequent computer representations of that object, whether in the MBD environment or in the drawings environment, unless the edited annotation information subsequently changes or is deleted. In a typical implementation, the AnnotationSet contains a reference to the object (e.g., by virtue of referencing the model and/or any corresponding engineering drawings) to logically associate the AnnotationSet with a particular modeled object. In view of the foregoing, it can be seen that the single AnnotationSet acts as an up-to-date, single source of truth for information regarding a corresponding logically-associated object.

If a computer running the xDrawing™ application, for example, were adapted to incorporate the functionalities disclosed herein, then within xDrawing™, the AnnotationSet would serve as a single source of truth for a design, whether represented in the 2D drawings side of that application or in the 3D MBD side of that application. Thus, if a particular view of the design were generated on the 2D drawing side of the application, the same view would be generated automatically on the 3D MBD side of the application. Likewise, if a particular view of the design were generated on the 3D MBD side of the application, the same view would be generated automatically on the 2D drawing side of the application. Additionally, if a particular annotation were added to a particular view of the design on the 2D drawing side of the application, that same annotation would be automatically applied to every other applicable view on both the 2D drawing side and the 3D MBD side of the application. Likewise, if a particular annotation were added to a particular view of the design on the 3D MBD side of the application, that same annotation would be automatically applied to every other applicable view on both the 3D MBD side and the 2D drawing side of the application. Also, any edits made to a view or annotation on either side of the application would automatically be applied to all other views on both sides of the application.

In a typical implementation, the systems and functionalities disclosed herein facilitate the use of visual representations of a design in either a 2D drawings environment and/or in 3D MBD environment. Wherever a user is accessing a visual representation of the particular design, the user can be assured that the information presented is up-to-date and accurate and consistent with all other visual representations in the application that may be available. These advantages may be realized automatically and through mechanisms that require virtually no additional effort by a human user. This also may ease the creation of viable designs by enabling a user to create a design in one environment (e.g., the drawings environment, which may be more familiar and easier to work within for certain users), while simultaneously and automatically generating substantively identical 3D MBD representations, which may be useful for a variety of applications that 2D drawings might fall short on, e.g., providing a deeper perspective on the design and intentions of the designer, generating CNC-compatible commands, etc. Alternatively, of course, a user who is more comfortable working directly in 3D MBD may design within that environment, while simultaneously and automatically generating substantively identical 2D drawings that match the 3D MBD work. Once finished, the user can easily print or transmit (e.g., to a builder) a comprehensive set of 2D engineering drawings, based on his or her 3D MBD design efforts.

Additionally, the systems and techniques disclosed herein typically make it very easy to switch between the 2D drawings environment and the 3D MBD environment so that a user may, for example, start working on a design in one environment (e.g., 2D drawings environment or 3D MBD environment) and, at some point, switch over to the other environment, and continue working on the design. The user can do that without concern (and without having to do any extra work to ensure) that the design will be fully and accurately represented in the second environment; it will. Of course, then, the user could work on the design in the second environment and subsequently switch back to the first environment, again without concern (and without having to do any extra work to ensure) that the design will be fully and accurately represented in the first environment; it will. There are, at all times, two sets of documents—one in each environment—both of which are maintained and kept up to date and accurate. The systems and techniques disclosed herein, therefore, provide for true bidirectionality.

In a typical implementation, the combination of features that result in these systems and functionalities will likely urge the industry to move more and more in the direction of adopting MBD, because with these systems and techniques, MBD representations of a design will be much easier to create and MBD will become much easier to work within.

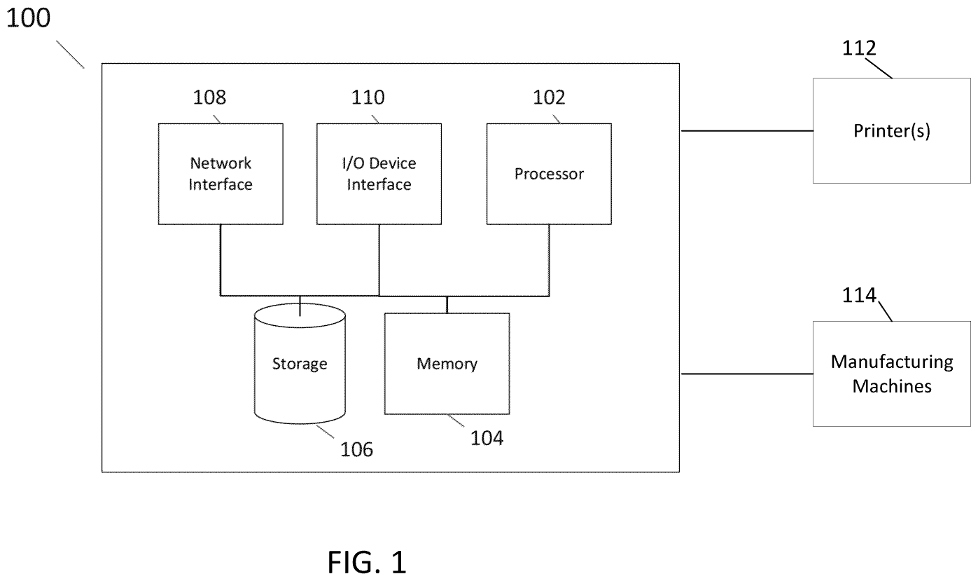

FIG. 1 is a schematic representation of an exemplary computer 100 configured to implement and/or facilitate the systems and techniques disclosed herein. More specifically, computer 100 is configured to facilitate computer-implemented design and modeling functionalities disclosed herein. In an exemplary implementation, those functionalities include those outlined above, including facilitating the generation and modification of model-based definition (MBD) elements within a drawing graphics sheet of a computer-aided drafting environment. In a typical implementation, the computer 100 may be configured to maintain an AnnotationSet to act as a single source of truth for both a 2D drawings side of an application (e.g., xDrawing™) and a 3D MBD side of the application so that a user can easily switch between the 2D drawings environment and the 3D MBD environment without concern (and without having to do any extra work to ensure) that the design will be fully and accurately represented in both environments. The systems and techniques disclosed herein may, in some instances, produce in a design of a real-world object to be manufactured. In some instances, after one or more of the techniques disclosed herein is performed, a real-world version of the object may be manufactured (e.g., by a CNC machine or other real-world manufacturing machine or system).

The computer 100 has a processor 102, computer-based memory 104, computer-based storage 106, a network interface 108, an input/output device interface 110, and a bus that serves as an interconnect between the components of the computer 100. The bus acts as a communication medium over which the various components of the computer 100 can communicate and interact with one another.

The processor 102 is configured to perform the various computer-based functionalities disclosed herein as well as other supporting functionalities not explicitly disclosed herein. Some such functionalities include or relate to generating and/or modifying MBD elements within a drawing graphics sheet of a computer-aided drafting environment. Typically, the processor 102, together with other computer components, performs these, and other, functionalities by executing computer-readable instructions stored on a computer-readable medium (e.g., in 104, 106, or elsewhere). In various implementations, some of these functionalities may be performed with reference to data stored in the computer-readable medium and/or received from some external source (e.g., an input/output (I/O) device via the I/O device interface 110 and/or from an external network via the network interface 108).

The computer 100 has volatile and non-volatile memory. More specifically, in a typical implementation, memory 104 provides a form of volatile storage storing computer-readable instructions that, when executed by the processor 102, cause the processor 102 to perform or facilitate performance of some (or all) of the computer-based functionalities disclosed herein. Moreover, in a typical implementation, storage 106 provides a form of non-volatile memory storing computer-readable instructions, such as instructions to implement an operating system, provide configuration information, etc. The various system memory resources (e.g., 104, 106) may store data to support computer functionalities disclosed herein and otherwise, as well. In a typical implementation, memory 104 stores computer-readable instructions that, when executed by the processor 102, cause the processor 102 to perform functionalities that present to a user at the computer 100 a computer-aided design program that incorporates and/or facilitates the functionalities disclosed herein, including those related to the generation and/or modification of MBD elements within a drawing graphics sheet of a computer-aided drafting environment. Examples of computer-aided design platforms suitable for adapting to incorporate the functionalities disclosed herein is the xDrawing™ application, which is available from Dassault Systèmes Corporation, the applicant of the current application. The xDrawing™ application, for example, has a 2D drawings environment and a 3D MBD environment. Implementations of the computer-aided design program, so adapted, would include one or more (or all) the functionalities disclosed herein.

The network interface 108 is a component that enables the computer 100 to connect to any one or more of a variety of external computer-based communications networks, including, for example, local area networks (LANs), wide area networks (WANs), such as the Internet, or the like. In various implementations, the network interface 108 can be implemented in hardware, software, or a combination of hardware and software. In some implementations, the network interface (or other interface) may provide a connection to other external machinery (e.g., one or more CNC machines, etc.).

The input/output (I/O) device interface 110 is a component that enables the computer 100 to interface with any one or more input or output devices, such as a keyboard, mouse, display, microphone, speakers, printers 112, etc. In various implementations, the I/O device interface can be implemented in hardware, software, or a combination of hardware and software. In a typical implementation, the computer may include one or more I/O devices (e.g., a computer screen, keyboard, mouse, printer, touch screen device, etc.) connected to the I/O device interface 110. These I/O devices (not shown in FIG. 1) act as human-machine-interfaces (HMIs) and are generally configured enable a human user to interact with the computer 100 to access and utilize functionalities, particularly those related to computer-aided design disclosed herein. The printer 112 in the illustrated implementation may be configured to print images based on the design information stored in the computer 100.

In an exemplary implementation, the computer 100 is connected to a display device (e.g., via the I/O device interface 110) and configured to present at the display device a visual representation of an interface to a product design environment, such as the ones provided by and within the xDrawing™ application. The interface and its visual representation on the computer-based display device, in a typical implementation, provides the user with access to the functionalities disclosed herein, and displays (e.g., on a display device coupled to the I/O device interface 110) a visual representation of drawings on drawing graphics sheets, 3D models, screenshots, etc.

In some implementations, the computer 100 and its various components may be contained in a single housing (e.g., as in a personal laptop) or at a single workstation. In some implementations, the computer 100 and its various components may be distributed across multiple housings, perhaps in multiple locations across a network. Each component of the computer 100 may include multiple versions of that component, possibly working in concert, and those multiple versions may be in different physical locations and connected via a network. For example, processor 102 in FIG. 1 may represent multiple discrete processors in different physical locations working together to perform processes attributable to processor 102 in a coordinated manner. A wide variety of possibilities regarding specific physical implementations are possible.

In various implementations, the computer 100 may have additional elements not shown in FIG. 1. These can include, for example, controllers, buffers (caches), drivers, repeaters, receivers, a graphics processing unit (GPU), etc. Furthermore, the interfaces (e.g., 108, 110) may include elements not specifically represented in FIG. 1, including, for example, address, control, and/or data connections to facilitate communications between the illustrated computer components.

In various implementations, the computer 100 may host, not only a CAD (or other) program that includes the functionalities disclosed herein, but also may host other programs, such as a CAM program that can be used in conjunction with the CAD program to generate machine-readable instructions for an external real-world machine 114 (e.g., a CNC machine). In such implementations, the computer 100 may be configured to transmit an output file, based on the instructions, to the external machine 114 via the network interface 108 and an external communications channel. The real-world machine 114 may be configured to receive those instructions for automated manufacturing of the product represented by a 3D model for MBD and execute the instructions. The CAD program, the CAM program, and any other programs may be stored in computer memory 104 and/or storage 106.

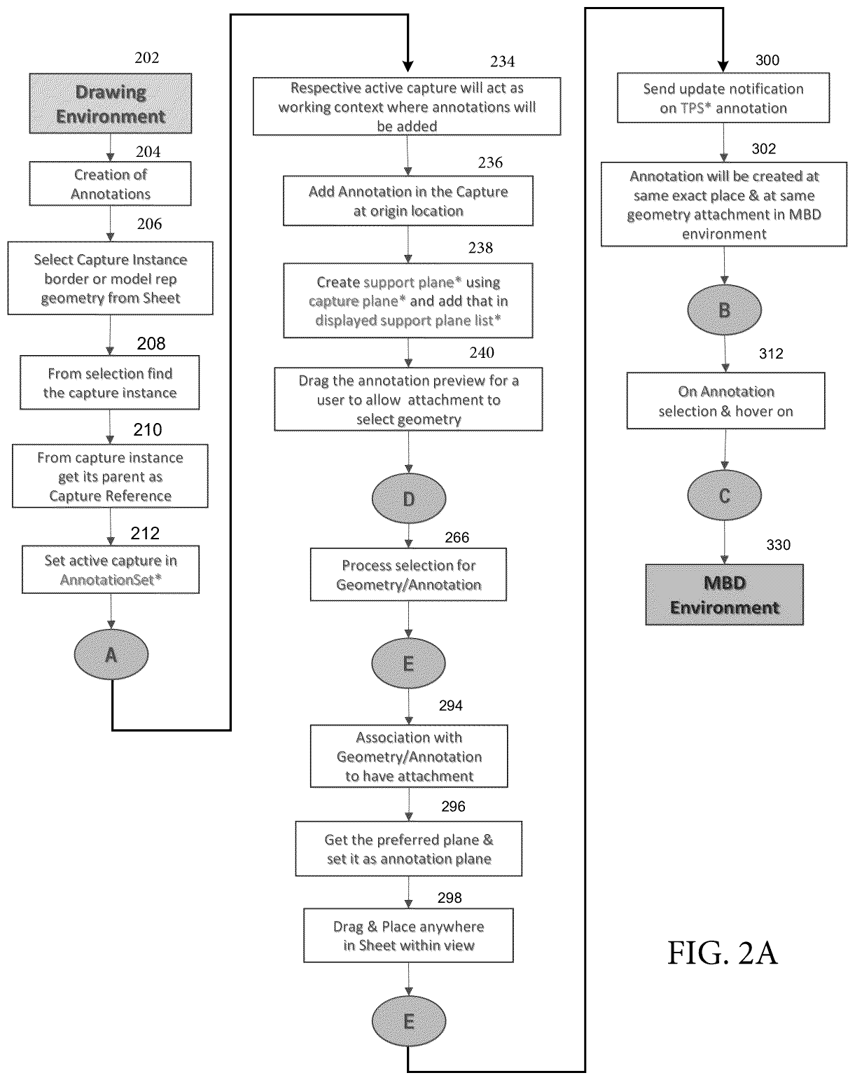

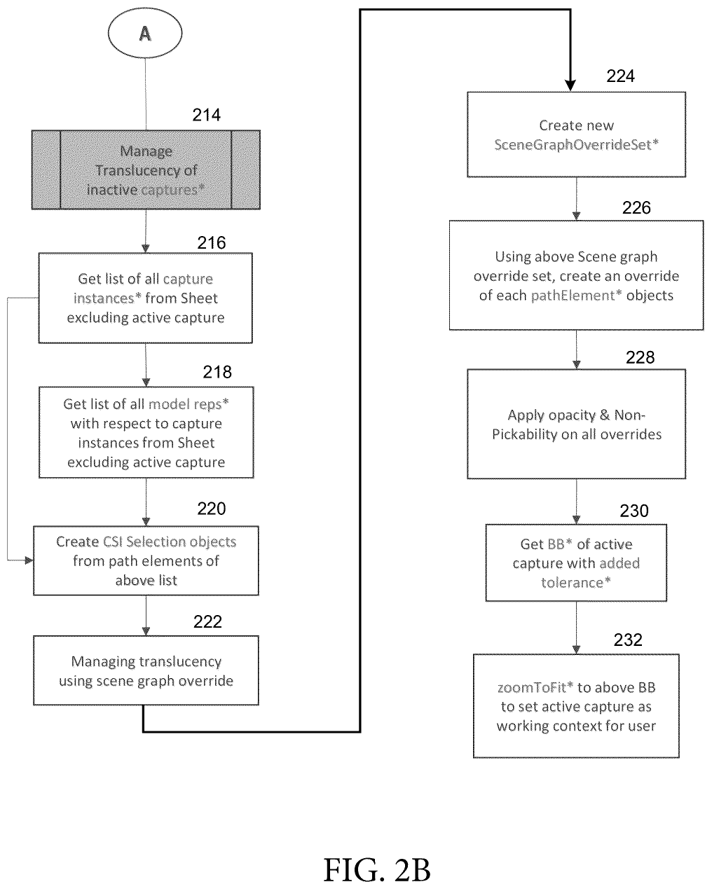

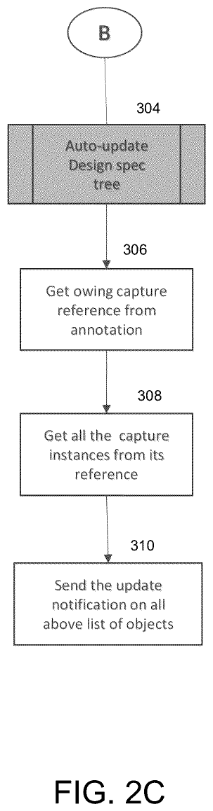

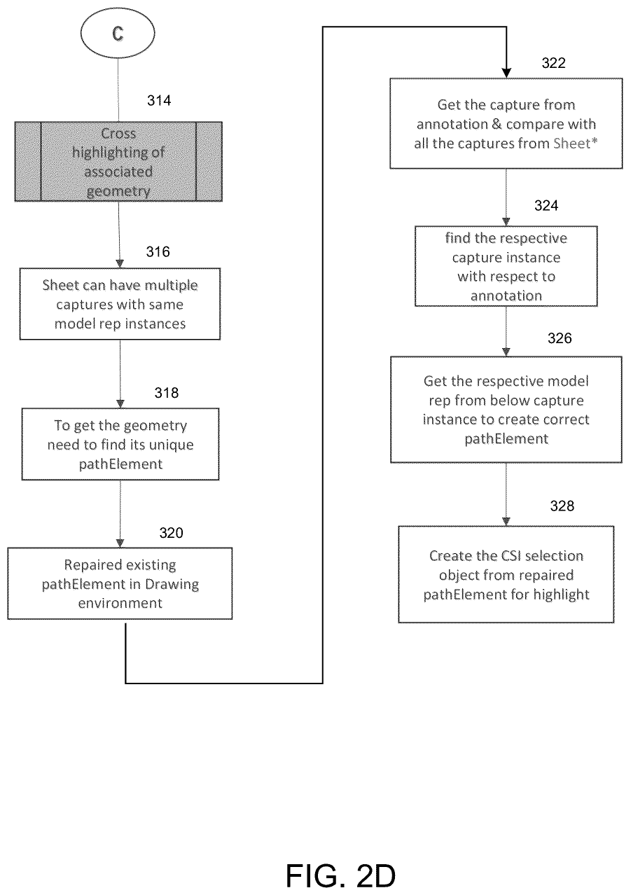

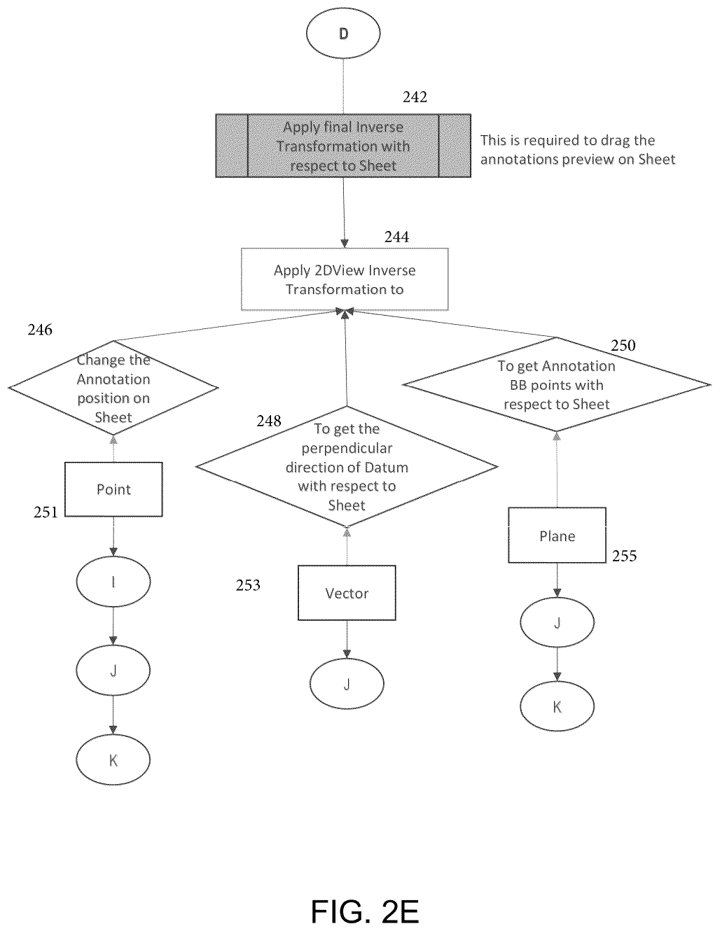

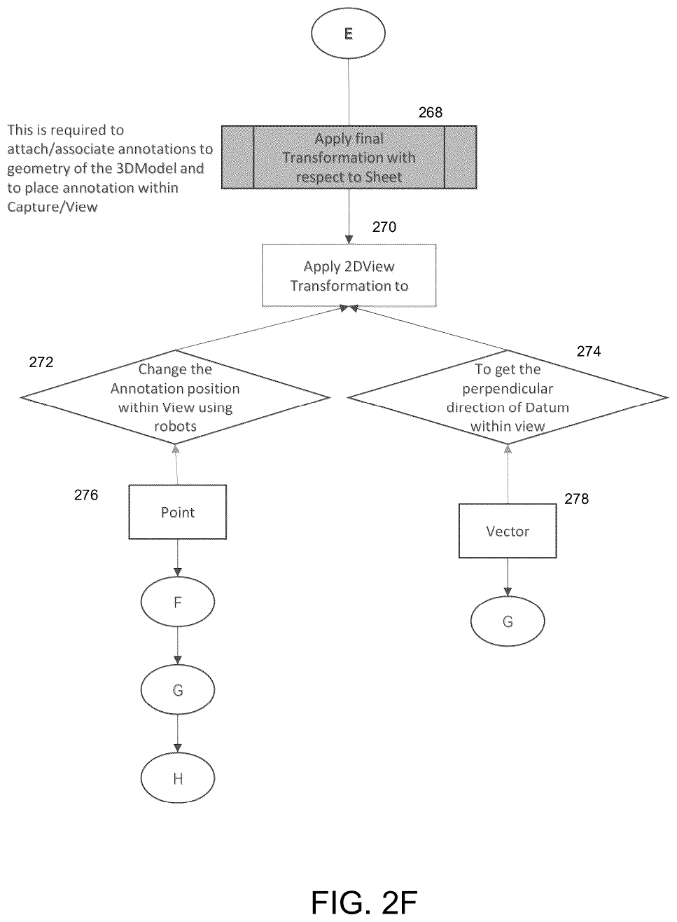

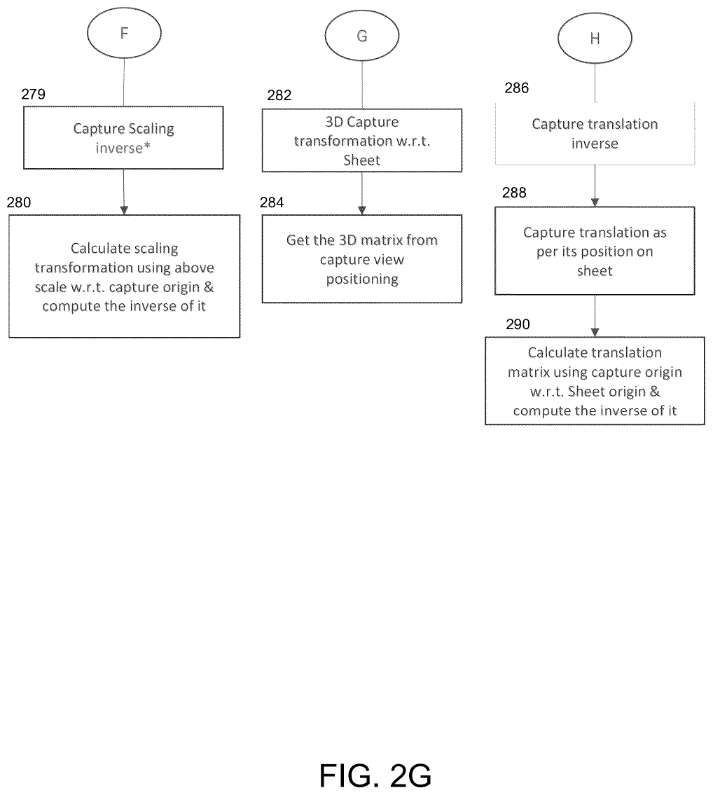

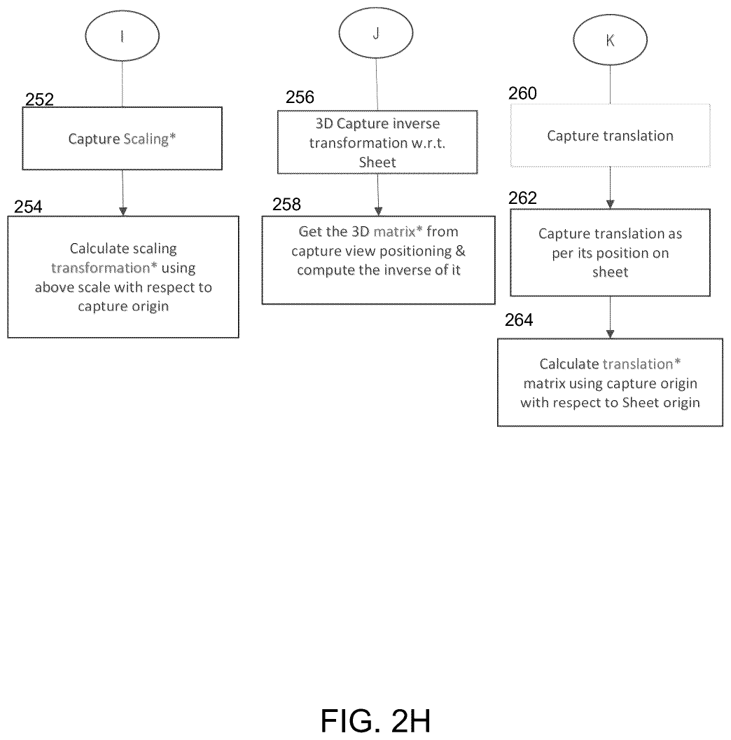

FIGS. 2A-2H represent a flowchart of a process that may be performed by the computer 100 of FIG. 1 to facilitate and/or perform the computer-implemented design and modeling functionalities disclosed herein including, for example, those relating to the generation and modification of model-based definition (MBD) elements within a drawing graphics sheet of a computer-aided drafting environment.

The flowchart in FIG. 2A starts with a human user (at 202) accessing and engaging with a computer-implemented drawing environment. The drawing environment may be provided by a computer-aided design (CAD) program executing on computer 100 and may include a two-dimensional (2D) drawing graphics sheet on the display screen of the user's computer 100. In one exemplary implementation, the drawing environment may be provided by and within the xDrawing™ application. The 2D drawing graphics sheet may include a virtual workspace where a user may create, edit, view and/or save one or more 2D drawings including associated drawing-based product definition information (e.g., product specifications such as dimensions, tolerances, materials, etc.) representing and associated with a real-world object to be manufactured. In a typical implementation, the human user would utilize the CAD program to access the 2D drawing graphics sheet to create and/or access and/or edit a 2D drawing(s) of the real-world object.

Next, according to the illustrated flowchart, the human user (at 204) creates one or more annotations in the drawing to define one or more characteristics of the design represented in the drawing. In a typical implementation, the user performs this step within the computer-implemented drawing environment. Annotating the drawing in this regard may include, for example, selecting a capture instance border or model geometry from the drawing sheet (at 206), invoking an annotation tool in the app, and adding text and/or symbols to the drawing representing characteristics, such as dimensioning and tolerancing, of the object represented in the drawing using the annotation tool. In some implementations, a single sheet in the 2D drawing environment may have one or more capture instances (each being represented on the sheet by a particular visual view of the object). Each capture instance may be associated with a particular parent (e.g., an image on the sheet from which the capture instance was derived and created). In some instances, a particular sheet may include a single parent and one or more capture instances associated with that parent. In some instances, a particular sheet may include more than one parent, with each parent having one or more capture instances on the sheet associated with that parent. In some instances, a capture instance on one sheet may be associated with a parent on another sheet.

Annotations may be added to a drawing in a variety of ways. In the SOLIDWORKS® computer program, for example, annotations may be added to a part or assembly document, then inserted into one or more drawings using annotation views or a Model Items Property Manager function. Alternatively, annotations may be inserted into a drawing directly. Annotations may be added to drawings in other ways, as well.

Each annotation added to the drawing may be stored as a part of an AnnotationSet, a dataset/container (stored in computer-based memory) for technological and/or geometrical object (project) specifications that are defined, for example, using Functional Tolerancing & Annotation features. AnnotationSet, in some implementations, may be stored as a Product Lifecycle Management (PLM) object within the Dassault Systemes 3DEXPERIENCE® platform in a cloud-based dataset (as opposed to a dataset stored as a file within a Microsoft Windows® or iOS® operating systems). The xDrawing™ app, from Dassault Systemes, for example, has the ability to create both model-based product definition (usually known as “model-based definition” or “MBD” as an abbreviation) and drawing-based product definition and save it all within a single document, referred to as an AnnotationSet. These functionalities are respectively provided in the xDrawing™ app via either an MBD environment or a 2D drawing environment, both of which are available within the xDrawing™ app.

The phrase “product definition” refers, for example, to the means by which requirements for a mechanical component or assembly (product) are identified and articulated via the use of a collection of annotations, metadata and/or other information, and the organization of such.

In the illustrated flowchart, the human user (at 206) selects a border or model rep geometry from a capture instance on the 2D drawing sheet. In a typical implementation, the user performs this step by selecting a visual in some implementations, this may be part of creating an annotation. In a typical implementation, a border is a user created element that surrounds an image or some portion of an image, for example, on a 2D drawing sheet. A border may be selected, for example, by a user positioning a mouse cursor on or near the border and then making a selection, or by virtue of creating the border, in which case the border is considered to be selected immediately after it has been created, as long as the user does not then click elsewhere on the 2D drawing or otherwise cause the border to become deselected. In some implementations, creating and/or selecting a border may cause the automatic selection of all drawing geometries contained completely within the border. In a typical implementation, a model rep geometry is any geometric entity that appear on the 2D drawing sheet that is selectable by user action (e.g., by the user positioning a mouse cursor over the model rep geometry and mouse clicking to select it). The model rep geometry may be or include any kind of geometric element (e.g., a line, a curve, a shape, etc.) represented, for example, in the 2D drawing onscreen at the computer. The phrase “capture instance” refers to a particular visual representation, in this case of an object represented in the 2D drawing sheet, annotated or otherwise, in a CAD-based environment. A capture instance may help to describe and define, for example, the tolerancing of the product.

Once the selection (at 206) is made, the computer 100 (at 208) finds the capture instance and from the capture instance, gets its parent as a capture reference (at 210). In a typical implementation, the computer 100 finds the capture instance (at 208) in computer-based memory and gets its parent (at 210) by identifying the parent that corresponds to the capture instance in computer-based memory. Next, the computer 100 (at 210) gets the parent of the capture instance and denotes the parent as a capture reference. In a typical implementation, each capture instance is created from a particular parent (e.g., a representation in computer memory, as part of the AnnotationSet, and/or onscreen that corresponds to the object represented in the capture instance). As such, each parent may have one or more associated capture instances. A particular parent may have multiple capture instances. In some such instances, the multiple capture instances may appear together on a single sheet or be spread across multiple different sheets. Denoting the parent as the capture reference may entail, for example, adding a designation associated with the parent in computer memory to indicate that the associated parent has a capture instance where the user has made a selection that remains active. The computer 100 (at 212) sets (or designates, e.g., in computer memory) the capture reference as the active capture in the AnnotationSet. This designation indicates that the capture reference (e.g., the parent of the capture instance at issue) is active (i.e., it corresponds to a capture instance where a user selection has been made and remains active). In a typical implementation, any annotations added by the user (e.g., to a selected capture instance) will be automatically added by the computer 100 (and saved) into the active capture in the AnnotationSet, which acts as a root component and a single source of truth for the design of the object in both the 2D drawings environment and the 3D MBD environment). Moreover, in a typical implementation, for any annotation so added, the computer 100 will automatically incorporate that annotation into any capture instance associated with that capture instance. In a typical implementation, this extends across the 2D drawing environment as well as the 3D MBD environment.

In a typical implementation, once the active capture is set in the AnnotationSet (at 212), a user may add (or edit) an annotation into the active capture through the user interface. In response, the computer 100 automatically updates every other associated capture instance with a corresponding version of the added annotation in the 2D drawing environment and the 3D MBD environment.

Referring now to FIG. 2B, in the illustrated flowchart, the computer 100 (see 214) manages translucency of inactive captures. In the SolidWorks® computer program, for example, a component may be made translucent by changing (e.g., increasing) a transparency value assigned to the component. In a typical implementation, increasing the transparency value assigned to a particular visual component makes that visual component more transparent (e.g., less visible). In some implementations, this helps the user understand which capture instance is active at a particular moment and which is/are not active.

According to the illustrated implementation, the computer 100 (at 216) gets a list of all capture instances represented on the 2D drawing graphics sheet excluding the active capture. In a typical implementation, the capture instances from the sheet will have been stored in memory (e.g., in 104, 106) as part of the AnnotationSet. In those implementations, the computer 100 may get the list of capture instances (at 216) excluding the active capture, by accessing the list in computer memory. Next, according to the illustrated implementation, the computer 100 (at 218) gets a list of all model reps with respect to the capture instances on the 2D drawing graphics sheet again excluding the active capture. In a typical implementation, a list of all model reps on a particular sheet will have been stored in memory (e.g., in 104, 106) as part of the AnnotationSet. In those implementations, the computer 100 may get this list of model reps (at 218) excluding the active capture by accessing the list in the computer memory.

Next, according to the illustrated implementation, the computer 100 (at 220) creates one or more CSI selection objects from path elements (e.g., the capture instance, the active capture (e.g., parent), and/or any other capture instances associated with the active capture) of the above list. A “CSI selection object” is a selection object created by CSI (Compute Server Infrastructure) which contains data about a 3D model, such as geometries (e.g., faces, edges, and/or points). In an exemplary implementation, a selection object is an object (that may appear on a user interface of computer 100) that is selectable (or selected) by a user. In a typical implementation, the selected object may appear visually distinct from other onscreen portions of a drawing. In an exemplary implementation, a path element is a selection element that identifies where the element is present in a 3D model representation, for example. Typically, every geometry/element/feature created has a unique traceable path in the model that a user (or the computer 100) can use to find and access which is known as pathElement (or path element). A path element may be a runtime object representing a path represented in the form of tree which can be used to traverse in model data to find an element. Typically, a path element may be represented by a string of characters used to uniquely identify a location in a directory structure. It may be composed by following the directory tree hierarchy in which components, separated by a delimiting character, represent each directory. In a typical implementation, the computer 100 (at 220) creates CSI selection objects to update the directory tree associated with a particular parent or other object so that the directory tree information will be and remain the same for the 2D drawing environment and for the 3D MBD environment. In an exemplary implementation, the user interface will simultaneously provide a directory tree on screen for both environments and the listing of CSI selection objects in each directory will match the other.

Next, according to the illustrated flowchart, the computer 100 (at 222) manages translucency using a scene graph override. In a typical implementation, the translucency is managed from the foregoing selection. A scene graph is a general data structure used by graphics editing applications, for example, that arranges logical and often spatial representation of a graphical scene. A scene graph override is able to apply a set of modifications, typically temporary modifications, (e.g., by adding translucency) to a graphical node occurrence. In an exemplary implementation, one or more (or all) of the following attributes may be overridden by a particular SceneGraphOverrideSet: color, opacity, full material, placement matrix, visibility (show/no show), pickability, etc.

Specifically, in the illustrated implementation, the computer 100 (at 224) creates a new SceneGraphOverrideSet dataset, which is a class of data (dataset) that is useful to apply these kinds of sets of temporary modifications to graphical node occurrences (e.g., to apply to a portion of a displayed drawing). Next, according to the illustrated implementation, the computer 100 (at 226) uses the aforementioned scene graph override set to create an override of each applicable pathElement object. More specifically, in a typical implementation, the computer 100 creates an override of each pathElement object (e.g., from which the CSI selection objects were created (at 220, above)). Thus, in a typical implementation, a scene graph override set is created for each capture instance for the CSI selection objects (created, e.g., at 220).

Next, according to the illustrated implementation, the computer 100 (at 228) applies appropriate opacity levels and/or non-pickability on all overrides. As an example, the portions of the displayed drawing where the override applies will subsequently have an opacity level as specified in connection with the SceneGraphOverrideSet. Moreover, any portions of the displayed drawings may be non-pickable (e.g., unable to be selected by a user) after the override is applied.

Next, according to the illustrated implementation, the computer 100 (at 230) gets/creates a bounding box (“BB”) with an added tolerance (e.g., of 12% (or 10% to 14%) of height of screen size) for the active capture. The phrase “bounding box” refers to a box (typically an imaginary or virtual rectangular box) that surrounds a 3D object or group of objects (e.g., in a virtual CAD environment). A bounding box may be sized to define the outermost extents or limits of an object(s), providing a rough and simple geometric representation of the object's (or objects') overall size and position. The added tolerance produces a small distance between the outermost extents of limits of the object(s) and the bounding box. More specifically, the added tolerance may be a specific margin or buffer around the 3D model content, for example, (in particular units) to ensure that the 3D model content is fully visible even if it extends slightly beyond the boundaries of the bounding box.

Next, according to the illustrated implementation, the computer 100 (at 232) applies a ZoomToFit functionality to the BB to set the active capture as a working context for the user. “ZoomToFit” refers to a computer-implemented functionality that causes a view to zoom in or out so that an entire model, assembly, or drawing sheet for example can be seen (e.g., on a computer display). In a specific implementation. Zoomtofit ensures that an entire drawing or model content fits within the visible area of the screen of the computer display. This can now act as a working context where the user can add annotations.

Referring again to FIG. 2A, next, the computer 100 (at 234) designates the active capture as a working context where annotations will be added. Next, the human user (at 236) adds an annotation in the active capture at an origin location on the sheet (e.g., in an x-y coordinate plane) in the 2D drawing environment.

Next, the computer 100 (at 238) creates a support plane using a capture plane. The support plane is defined, e.g., by plane axes and directions, and origin. The support plane, in a typical implementation, may be in the capture plane. A “support plane” is a two-dimensional surface, in a virtual (e.g., CAD-based) environment, on which one or more annotations may be drawn. A “capture plane” is a virtual two-dimensional surface that provides a point of view for the 3D model. The computer 100 adds an identification of the support plane into a “displayed support plane list,” which is a list of (typically all available) support planes, from which all annotations are able to be viewed. In a typical implementation, each capture is associated, via data in computer-based memory, to a particular support plane.

Next, in the illustrated implementation, the user, interacting with the computer 100, (at 240) drags an annotation preview for a user to allow attachment to select geometry. The dragging may be accomplished in a number of different ways. In one such way, the user uses a mouse to drag the annotation preview. Thus, a new annotation may be created and, shown in preview as, attached to a select geometry.

In one example, the preview, the select geometry, and the new annotation all lie on a sheet in a plane (e.g., an x-y plane in a two-dimensional Cartesian coordinate system) in the 2D drawing environment. The select geometry in particular will appear and be contained on the sheet entirely and contained in the two-dimensions (e.g., within a plane on an x-y plane of the two-dimensional Cartesian coordinate system). The select geometry is in the x-y plane in this example because the sheet where the select geometry appears is on the x-y plane in this example. In three dimensions, however, the select geometry, in this example, might be represented in a manner that it extends or exists, at least in part, outside of the x-y plane (e.g., extending into, or existing at least partially, in the z direction of a three-dimensional Cartesian coordinate system that includes an x-axis, a y-axis and a z-axis) within a corresponding capture in the three-dimensional MBD environment.

Referring now to FIG. 2E, the computer 100 applies a final inverse transformation (see 242) with respect to the sheet. In a typical implementation, this inverse transformation transforms the select geometry from a first version (e.g., in a sheet in the 2D drawing environment) to a second, transformed version (e.g., for a view in a capture within the 3D MBD environment). This is done with respect to the sheet, because the computer 100 has the coordinates with respect to the sheet in the 2D drawing environment), not with respect to the capture in the 3D MBD environment. As noted in the figure, applying the final inverse transformation with respect to the sheet is required to drag the annotations preview on the sheet. As represented in the figure, the 2D inverse transformation may be applied, as applicable, (see 244) to change an annotation position on the sheet (246), to get a perpendicular direction of a datum with respect to the sheet (248), and/or to get annotation bounding box (BB) points (e.g., coordinates) with respect to the sheet. The transformation applied in this regard is referred to as an inverse transformation because the transformation is going from the sheet (e.g., in the 2D drawing environment) to the view (e.g., in the 3D MBD environment). As indicated in the illustrated flowchart, if the 2D inverse transformation is applied to change an annotation position on the sheet (246), then the process yields a point (at 251) and the transformation is applied to the point, if the 2D inverse transformation is applied to get a perpendicular direction of a datum with respect to sheet then the process yield a vector (at 253) and the transformation is applied to the vector, and if the 2D inverse transformation is applied to get annotation bounding box points with respect to the sheet, then the process yields a plane (at 255) and the transformation is application to the plane.

There are a number of ways in which the type of final inverse transformation may be implemented. “Transformation,” in a general sense, refers to a process that is related to changing the position, orientation, size, or shape of an object (e.g., in a virtual or CAD-based environment). In a typical implementation, a normal (i.e., non-inverse) transformation may refer to a transformation in one direction (e.g., from a view in a 3D environment to a sheet in a 2D environment), whereas an inverse transformation may refer to a transformation in the opposite direction. A transformation may be represented, for example, as a function that maps points from one coordinate system (e.g., in one environment) to another (e.g., a different coordinate system, e.g., in a different environment).

According to the illustrated flowchart, if a point (251) is applied to the 2D inverse transformation (244) (e.g., to change an annotation position), then the transformation involves executing one or more of the processes respectively represented in FIG. 2E as I, J, and K (or sequentially executing all three). Processes I, J, and K from FIG. 2E are represented by three separate sequences of computer-implemented steps, each amounting to a transformation, in FIG. 2H. Referring now to FIG. 2H, the first sequence of computer-implemented steps (I) includes the computer 100 (at 252) capturing scaling (e.g., scaling of the 3D capture). “Scaling” generally relates to the size of one or more objects or geometric figures on a drawing sheet and refer to a process that involves setting or changing the size of a visual object or geometric figure, for example, typically while preserving its shape. Scaling can occur or exist in one or more dimensions and scaling may change size, which may result in an enlargement or reduction of the object, along any one or more than one dimensions. Scaling can be represented, for example, as a ratio (e.g., 1:1, 1:2, etc.), which may be stored in computer-based memory in logical association with the design of interest.

In the illustrated implementation, the computer 100 (at 254) calculates a scaling transformation, using the aforementioned scaling (or scale) of the 3D capture with respect to the capture origin (e.g., in the 2D drawing environment). Specifically, the scaling transformation may be (or be based on) a ratio of actual distances (e.g., in one or more directions) that represent a particular dimension of the represented design, for example, in the 2D drawing environment and the 3D MBD environment.

The sequence of computer-implemented steps (J), in the illustrated implementation, includes the computer 100 (at 256) performing a three-dimensional (3D) capture inverse transformation with respect to the sheet. The computer 100 (at 258) gets a 3D matrix from capture view positioning and computes the inverse of it. In an exemplary implementation, a matrix may include a rectangular array of numbers arranged in rows and columns, stored in computer-based memory (e.g., 104/106). The inverse of a square matrix is another matrix that, when multiplied with the original matrix, results in the identity matrix. Specifically, for example, for a square matrix A, if there exists another matrix A⁻¹, such that, A*A⁻¹=A⁻¹*A=I, where I is the identity matrix, then A⁻¹ is the inverse of A. In a typical implementation, the computer 100 may place the 3D capture onto a corresponding sheet.

The sequence of computer-implemented steps (K), in the illustrated implementation, includes the computer 100 (at 260) capturing a translation. A “translation” generally involves a movement of one or more objects or graphical elements from one location on a sheet (e.g., on a computer display screen) to another location, typically without changing its size, shape, or orientation. Translation typically includes shifting each point of the object(s) by a certain amount along specified axes. A user may be able to perform or cause a translation by selecting one or more on sheet objects and dragging them across the sheet. The computer 100, according to the illustrated implementation, captures the translation as per its position on the sheet (at 262). The computer 100 then (at 264) calculates a translation matrix using a capture origin with respect to the sheet origin meaning calculating how the position of capture can be expressed relative to the origin (reference point) of sheet. The translation matrix, in a typical implementation, describes the relationship between translation in one environment (e.g., the 2D drawing environment) to another environment (e.g., the 3D MBD environment).

In a typical implementation, the scaling transformation (at 254), the 3D matrix (at 258), and/or the translation matrix (at 264) may be utilized to transform changes between environments (e.g., 2D drawing environment to 3D MBD).

Referring again to FIG. 2E, according to the illustrated flowchart, if a vector (253) is applied to the 2DView inverse transformation (244) (e.g., to get the perpendicular direction of a datum with respect to the sheet), then the transformation involves executing only one of the processes represented in FIG. 2E, specifically process J, represented in FIG. 2H and discussed above in some detail.

Referring again to FIG. 2E, according to the illustrated flowchart, if a plane (255) is applied to the 2DView inverse transformation (244) (e.g., to get annotation bounding box points with respect to the sheet), then the transformation involves executing one or more of the processes represented in FIG. 2E as process J and process K, depending on the circumstances. Process J and process K are represented in FIG. H and discussed above in some detail.

Referring again to FIG. 2A, the process includes a step for selecting geometry or an annotation (at 266). At that point, the computer proceeds to process E, which is represented in FIG. 2F.

Related code follows:

```
  void SWXCSDrwUtils::Apply2DViewInverseTransformationToVector(const
SWXCSIMBDCapture_var& ispCapRef, CATMathVector& ioVector)
{
  if (ispCapRef != NULL_var) {
    //Apply inverse of 2DView transformation matrix
    CATMathTransformation viewTransformationInverse;
    CATIDifView3DPosition_var spView3DPos = ispCapRef;
    if (NULL_var != spView3DPos) {
      CATMathTransformation viewTransformation;
      spView3DPos−>Get3DMatrix(viewTransformation);
      viewTransformation.ComputeInverse(viewTransformationInverse);
    }
    ioVector = viewTransformationInverse * ioVector;
    ioVector.Normalize( );
  }
}
void SWXCSDrwUtils::Apply2DViewInverseTransformationToPlane(const SWXCSIMBDCapture_var&
ispCapRef, const CATMathPlane& iViewPlane, CatMathPlane& ioPlane)
{
  if (ispCapRef != NULL_var) {
    // Apply inverse of 2DView transformation matrix
    CATMathTransformation inverseTransformation;
  CATIDifView3DPosition_var spView3DPos = ispCapRef;
    if (NULL_var != spView3DPos)
    {
      CATMathTransformation viewTransfo;
      spView3DPos−>Get3DMatrix(viewTransfo);
      viewTransfo.ComputeInverse(inverseTransformation);
    }
    // Apply 2DView origin translation
    CATMathTransformation translationTransform(iViewPlane.GetOrigin( ) − CATMath0);
    ioPlane = inverseTransformation * ioPlane;
    ioPlane = translationTransform * ioPlane;
  }
}
void SWXCSDrwUtils::Apply2DViewInverseTransformationToPoint(const SWXCSIMBDCapture_var&
ispCapRef, Const CATMathPlane& iViewPlane,
```

CATMathPoint& ioPoint, const double& iViewScale)

```
{
  if (ispCapRef !− NULL_var) {
    // Apply inverse of 2DView transformation matrix
    CATMathTransformation viewTransformationInverse;
  CATIDifView3DPosition_var spView3DPos = ispCapRef;
    if (NULL_var != spView3DPos) {
      CATMathTransformation viewTransformation;
      spView3DPos−>Get3DMatrix(viewTransformation);
      viewTransformation.ComputeInverse(viewTransformationInverse);
    }
    // Apply 2DView origin translation
  CATMathTransformation translationTransform(iViewPlane.GetOrigin( ) − CATMath0);
    // Apply 2DView scale transformation
    CATMathTransformation scaleTransform(iViewPlane.GetOrigin( ), iViewScale);
    ioPoint = viewTransformationInverse * ioPoint;
    ioPoint = translationTransform * ioPoint;
    ioPoint = scaleTransform * ioPoint;
  }
}
```

Referring now to FIG. 2F, the computer 100 applies a final transformation (see 268) (e.g., to the selected geometry or annotation) with respect to the sheet. As noted in the flowchart, in a typical implementation, this is required to attach/associate annotations to geometry of the 3D model and to place annotations within capture/view. In a typical implementation, this transformation transforms the selected geometry or annotation from a first version to a second transformed version. As indicated in the illustrated flowchart, if the 2DView transformation is applied to change the annotation position within view (at 272), then the process yields a point (276) and the transformation applies to the point. If the 2DView transformation is applied to get the perpendicular direction of a datum within view, then the process yields a vector (278) and the transformation applies to the vector.

According to the illustrated flowchart, if a point (276) is applied to the 2DView transformation (270) (e.g., to change an annotation position within view), then the transformation involves executing one or more of the processes respectively represented in FIG. 2G as F, G, and H (or sequentially executing all three). Processes F, G, and H from FIG. 2F are represented by three separate sequences of computer-implemented steps, each amounting to a transformation, in FIG. 2G. Referring now to FIG. 2G, the first sequence of computer-implemented steps (F) includes the computer 100 (at 279) capturing a scaling inverse. A scaling inverse represents the reverse (or inverse) of the scaling captured (at 252, for example). The computer 100 (at 280) calculates scaling transformations using the above scale with respect to the capture origin and computes an inverse of it.

The second sequence of computer-implemented steps (G) in FIG. 2G includes the computer 100 (at 282) performing a 3D capture transformation with respect to the sheet. The computer 100 (at 284) gets a 3D matrix from a capture view positioning from the 3D MBD environment with respect to the sheet.

The third sequence of computer-implemented steps (H) in FIG. 3 includes computer 100 (at 286) capturing a translation inverse. The computer 100 (at 288) captures a translation as per its position on the sheet. The computer 100 (at 290) calculates a translation matrix using a capture origin with respect to a sheet origin and computes an inverse of it.

A related code follows:

void SWXCSDrwUtils::Apply2DViewTransformationToPoint(const SWXCSIMBDCapture_var& ispCapRef,
const CATMathPlane& iViewPlane,

CATMathPoint& ioPoint, const double& iViewScale)

```
{
  if (ispCapRef != NULL_var) {
    // Apply inverse of 2DView scale transformation
    CATMathTransformation scaleTransform(iViewPlane.GetOrigin( ), iViewScale);
    CATMathTransformation scaleTransformInverse;
    scaleTransform.Inverse(scaleTransformInverse);
    // Apply inverse of 2DView origin translation
    CATMathVector translatedDir = iViewPlane.GetOrigin( ) − CATMath0;
    CATMathTransformation translationTransform(translatedDir);
    CATMathTransformation translationTransformInverse;
    translationTransform.ComputeInverse(translationTransformInverse);
    // Apply 2DView transformation matrix
    CATMathTransformation viewTransformation;
  CATIDifView3DPosition_var spView3DPos) {
    if (NULL_var != spView3DPos) {
      spView3DPos−>Get3DMatrix(viewTransformation);
    }
    ioPoint = scaleTransformInverse * ioPoint;
    ioPoint = translationTransformInverse * ioPoint;
    ioPoint = viewTransformation * ioPoint;
  }
}
```

According to the illustrated flowchart, if a vector (278) applies to the 2DView transformation (270) (e.g., to get the perpendicular direction of a datum within view), then the transformation involves executing the process represented in FIG. 2G as G. Process G from FIG. 2G is represented by a sequence of computer-implemented steps, each amounting to a transformation, in FIG. 2G, and each discussed above in some detail.

A related code follows:

```
void SWXCSDrwUtils::Apply2DViewTransformationToVector(const SWXCSIMBDCapture_var& ispCapRef,
CATMathVector& ioVector)
{
  if (ispCapRef != NULL_var) {
    // Apply inverse of 2DView transformation matrix
    CATMathTransformation viewTransformation;
    CATIDifView3DPosition_var spView3DPos = ispCapRef;
    if (NULL_var != spView3DPos) {
      spView3DPos−>Get3DMatrix(viewTransformation);
    }
    ioVector = viewTransformation * ioVector;
    ioVector.Normalize( );
  }
}
```

Referring again to FIG. 2A, the process includes the computer 100 (at 294) creating an association with geometry/annotation which is selected to have attachment. Next (at 296), the computer 100 gets a preferred plane and sets it as an annotation plane. Here, a plane that has more visible area is likely to be preferred because it will provide a clearer view of the annotation or better interaction for operations like manipulation, selection etc. Thus, in a typical implementation, for a selected edge and an associated capture, the computer identifies the preferred plane and the plane is saved to the annotation so that the annotation will be visible on the same plane as capture. Next (at 298), the computer 100 enables the user to drag and/or place the annotation plane anywhere on the sheet within view of the computer display screen. Then, the computer 100 follows the process outlined in FIG. 2F and described above so that all will be reflected in the 3D MBD environment as well.

After that, and referring again to FIG. 2A, the computer 100 (at 300) sends an update notification on TPS annotation. TPS refers to “Technological Product Specification.” A TPS domain may be described using TPS objects (representing tolerancing sets, TPS Features, and Technologically and Topologically Related Surfaces, for example), and/or interfaces. According to the illustrated process (at 302), an annotation will be (and eventually is) created (by computer 100) at the same exact place and at the same geometry attachment in the model-based definition (MBD) environment.

Referring now to FIG. 2C, according to the illustrated implementation, the process includes the computer 100 (at 304) automatically updating a design specification tree. For example, when a notation has been added to, edited, or deleted from a particular capture instance, the computer 100 automatically updates all other related objects/instances represented in a design specification tree (e.g., onscreen and/or stored in computer memory) for that design. In a typical implementation, this includes updates to both instances/objects in the 2D drawings environment and instances/objects in the 3D MBD environment.

As shown, the computer 100 (at 306) gets a capture reference for the capture instance where the annotation has been added, editing, or deleted (i.e., the capture instance that owns the change in annotation). Then, the computer 100 (at 308) identifies (e.g., from information in computer memory) a list all the objects/instances that are related to the reference. The computer 100 then (at 310) sends an update notification to all of the objects/instances in the above list. In a typical implementation, each of the objects/instances is automatically updated to include and reflect the addition, edit, or deletion from the capture instance where the annotation changes took place.

A related code follows:

```
          //Tree update for [Active] keyword management
          if (!!spMBDCurrentCapInst)
            SWXCSCommonFeatureServices::NotifyViewModelTree
          Update(spMBDCurrentCapInst);
          if (!! spOldActiveCapInst)
            SWXCSCommonFeatureServices::NotifyViewModelTree
          Update(spOldActiveCapInst);
          if (!!mspCurDifSheetInst)
            SWXCSCommonFeatureServices::NotifyViewModelTree
          Update(mspCurDifSheetInst);
        }
      }
      /*
        must call SetVisualizationMode(CATIDifAnnotationSetSession:mode2D)
        as SetCurrentDIFCapture by default set the mode to 3D
    */
    spAnnotationSet−>SetVisualizationMode(CATIDifAnnotationSetSession::mode2D);
    /*
      GSA13 : Extract the background pathElements only after calling all necessary
  updates (like to − mspCurDifSheetInst,spMBDCurrentCapInst)
    */
    if (applyOverrides) {
      if (!!mspCurDifSheetInst)
      {
        SWXCSIDrw2DViewInstance_var spActiveViewInst =
  mspCurDifSheetInst−>GetActive2DViewInstance( );
        if (!!spActiveViewInst)
          hr =
  SWXCSMBDVisuUtils::SetDrwViewRelatedPathElem(mspCurDifSheetInst, oParams);
      }
    }
    hr = S_OK;
  }
  return hr;
}
```

Referring again to FIG. 2A, the computer (at 312) illustrates annotations on annotation selection and/or when hovering over an object having an annotation.

Next, and referring now to FIG. 2D, the computer 100 (314) cross highlights of associated geometry. According to 316, the sheet can have multiple captures with the same model rep instances, and to get the geometry, the computer 100 (at 318) finds its unique pathElement. The computer 100 (at 320) repairs the existing pathElement in the drawing environment. A related code follows:

```
CATPathElement* SWXCSMBDAnnUtils::RepairPathElementIn2DContext(const
SWXIMBDAnnotation_var& iAnnotation, CATPathElement*& iPathElt)
{
  CATPathElement* oRepairedPathElt = NULL;
  SWXCSIMBDAnnotationSet_var spAnnotationSet =
SWXCSMBDPLMUtils::GetActiveAnnotationSet( );
  if (!!iAnnotation && !!spAnnotationSet && spAnnotationSet−>IsDrawingMode( )) {
    //Add root “Annotation Set”
    oRepairedPathElt = new CATPathElement(spAnnotationSet);
    SWXCSIDrwDifLayout_var spDifLayout = spAnnotationSet−>GetCurrentDIFLayout( );
    if (!!spDifLayout)
    {
      // Add drawing root “Dif Layout”
      oRepairedPathElt−>AddChildElement(spDifLayout);
```

Next (at 322), the computer 100 gets the capture from annotation and compares it with all the captures from the sheet. The computer 100 (at 324) finds the respective capture instance with respect to the annotation. Then the computer 100 (at 326) gets the respective model rep from below capture instance to create a correct pathElement. Next, the computer 100 (at 328) creates a CSI selection object from the repaired pathElement for highlight. Typically, this is a selection element which tells where it is present in the 3D model representation. Every geometry/element/feature created has a unique traceable path in the model using which we can find and access it which is known as pathElement. Also, it is a runtime object representing a path in form of tree which we use to traverse in model data to find the element.

Referring again to FIG. 2A, the computer 100 (at 330) then operates in the MBD environment, where views and annotations created and/or edited in the drawing environment will be accessible and/or viewable.

A number of embodiments of the invention have been described. Nevertheless, it will be understood that various modifications may be made without departing from the spirit and scope of the invention.

For example, the systems and techniques disclosed herein may be incorporated into, or used with the Manufacturing Definition Creator role in the xDrawing™ app. However, other possibilities, such as the CATIA branded version of the xDrawing™ app are possible as well.

Various aspects of the subject matter disclosed herein can be implemented in digital electronic circuitry, or in computer-based software, firmware, or hardware, including the structures disclosed in this specification and/or their structural equivalents, and/or in combinations thereof. In some embodiments, the subject matter disclosed herein can be implemented in one or more computer programs, that is, one or more modules of computer program instructions, encoded on computer storage medium for execution by, or to control the operation of, one or more data processing apparatuses (e.g., processors). Alternatively, or additionally, the program instructions can be encoded on an artificially generated propagated signal, for example, a machine-generated electrical, optical, or electromagnetic signal that is generated to encode information for transmission to suitable receiver apparatus for execution by a data processing apparatus. A computer storage medium can be, or can be included within, a computer-readable storage device, a computer-readable storage substrate, a random or serial access memory array or device, or a combination thereof. While a computer storage medium should not be considered to be solely a propagated signal, a computer storage medium may be a source or destination of computer program instructions encoded in an artificially generated propagated signal. The computer storage medium can also be, or be included in, one or more separate physical components or media, for example, multiple CDs, computer disks, and/or other storage devices.

Certain operations described in this specification (e.g., aspects of those attributable to a computer) can be implemented as operations performed by a data processing apparatus (e.g., a processor/specially programmed processor/computer) on data stored on one or more computer-readable storage devices or received from other sources, such as the computer system and/or network environment described herein. The term “processor” (or the like) encompasses all kinds of apparatus, devices, and machines for processing data, including by way of example a programmable processor, a computer, a system on a chip, or multiple ones, or combinations, of the foregoing. The apparatus can include special purpose logic circuitry, e.g., an FPGA (field programmable gate array) or an ASIC (application specific integrated circuit). The apparatus can also include, in addition to hardware, code that creates an execution environment for the computer program in question, for example, code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing, and grid computing infrastructures.

While this specification contains many specific implementation details, these should not be construed as limitations on the scope of any inventions or of what may be claimed, but rather as descriptions of features specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations may be described herein as occurring in a particular order or manner, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

An example of code snippets of an implementation of certain techniques disclosed herein is provided below. Variations are, of course, possible.

What is claimed is:

1. A computer-based method comprising:
displaying a two-dimensional view of an object on a sheet on a graphical user interface of a two-dimensional drawing environment in a computer-aided drafting application that is configured to provide access to the two-dimensional drawing environment and a three-dimensional model-based definition environment;
receiving an annotation attached to a selected geometry on the displayed object in the two-dimensional drawing environment;
applying a two-dimensional view inverse transformation to the annotation attached to the selected geometry to produce a transformed version of the annotation; and
attaching the transformed version of the annotation to a geometry in a three-dimensional version of the object in the three-dimensional model-based definition environment.

2. The computer-based method of claim 1, wherein the annotation is attached to the geometry in the three-dimensional version of the object at a position that corresponds precisely to a position of the annotation attached to the selected geometry in the two-dimensional drawing environment.

3. The computer-based method of claim 1, further comprising:
storing the annotation attached to the selected geometry in the two-dimensional drawing environment and the annotation attached to the geometry in the three-dimensional model-based definition environment in a single data set in computer-based memory, wherein the single data set is configured to serve as a single source of truth for design of the object as represented in both the two-dimensional environment and the three-dimensional model-based definition environment.

4. The computer-based method of claim 1, wherein applying the two-dimensional view inverse transformation to the annotation attached to the selected geometry comprises:
capturing scaling data; and
calculating a scaling transformation using the scaling data with respect to a capture origin.

5. The computer-based method of claim 1, wherein applying the two-dimensional view inverse transformation to the annotation attached to the selected geometry comprises:
getting a 3D matrix from capture view positioning; and
computing an inverse of the 3D matrix.

6. The computer-based method of claim 1, wherein applying the two-dimensional view inverse transformation to the annotation attached to the selected geometry comprises:
capturing translation data from a sheet in the two-dimensional drawing environment; and
calculating a translation matrix using a capture origin with respect to a sheet origin from the translation data.

7. The computer-based method of claim 1, further comprising applying a two-dimensional transformation with respect to a sheet in the 2D drawing environment.

8. The computer-based method of claim 7, wherein applying the two-dimensional transformation with respect to the sheet in the 2D drawing environment comprises:
capturing scaling data; and
calculating a scaling transformation with respect to a capture origin; and
computing an inverse of the scaling transformation.

9. The computer-based method of claim 7, wherein applying the 2D transformation with respect to the sheet in the 2D drawing environment comprises:
getting a 3D matrix from capture view positioning; and
computing an inverse of the 3D matrix.

10. The computer-based method of claim 7, wherein applying the 2D transformation with respect to the sheet in the 2D drawing environment comprises:
capturing translation data from a sheet in the two-dimensional drawing environment; and
calculating a translation matrix using a capture origin with respect to an origin in the sheet origin from the translation data; and
computing an inverse of the translation matrix.

11. The computer-based method of claim 1, further comprising:
displaying a plurality of captures;
designating, in a data set in computer memory, a selected one of the plurality of captures as an active capture, wherein unselected captures are designated as inactive captures; and
managing translucency of the inactive captures.

12. The computer-based method of claim 11, wherein managing translucency of the inactive captures comprises:
creating selection objects from path elements based on a list of all capture instances from the sheet, excluding the active capture, and a list of all model reps in the capture instances, excluding the active capture;
using a scene graph override set to create an override of each path element represented by the selection objects; and
applying opacity and making all objects non-pickable in all overrides.

13. The computer-based method of claim 12, further comprising:
creating a bounding box for the active capture with an added tolerance; and
zooming to fit the bounding box on screen to set the active capture as a working context for the user.

14. The computer-based method of claim 1, further comprising automatically updating a design specification tree for a design in response to an annotation being added to, edited, or deleted from a selected capture instance so that all related objects/instances represented in the design specification tree for that design are updated to reflect the addition, edit or deletion.

15. The computer-based method of claim 14, wherein automatically updating the design specification tree comprises:
obtaining a capture reference for the capture instance where the annotation has been added, editing, or deleted;
identifying all the objects/instances represented in the design specification tree that are related to the capture reference; and
sending an update notification to all of the identified objects/instances to update so as to include and reflect the addition, edit, or deletion.

16. The computer-based method of claim 1, further comprising cross highlighting a geometry associated with the annotation upon selection and/or hovering over the annotation, wherein a sheet where the annotation appears has multiple captures with same model rep instances.

17. The computer-based method of claim 16, wherein the cross highlighting comprises:
identifying the associated geometry on a sheet by finding a unique path element for the associated geometry;
creating a selection object based on a repaired version of the path element; and
applying highlighting based on the selection object.

18. The computer-based method of claim 1, further comprising manufacturing a real-world version of the object using one or more real-world machines.

19. A system comprising:
a computer comprising:
a computer processor; and
computer-based memory operatively coupled to the computer processor, wherein the computer-based memory stores computer-readable instructions that, when executed by the computer processor, cause the computer system to perform a process comprising:
displaying a first two-dimensional view of an object on a sheet on a graphical user interface of a two-dimensional drawing environment in a computer-aided drafting application that is configured to provide access to the two-dimensional drawing environment and a three-dimensional model-based definition environment;
receiving an annotation attached to a selected geometry on the displayed object in the two-dimensional drawing environment;
applying a two-dimensional view inverse transformation to the annotation attached to the selected geometry to produce a transformed version of the annotation; and
attaching the transformed version of the annotation to a geometry in a three-dimensional version of the object in the three-dimensional model-based definition environment.

20. The system of claim 19, further comprising:
one or more real-world manufacturing machines coupled to the computer,
wherein the computer is configured to feed digital data directly into the one or more real-world manufacturing devices to manufacture a real-world version of the object.

21. A non-transitory computer readable medium having stored thereon computer-readable instructions that, when executed by a computer-based processor, cause the computer-based processor to perform a process comprising:
displaying a first two-dimensional view of an object on a sheet on a graphical user interface of a two-dimensional drawing environment in a computer-aided drafting application that is configured to provide access to the two-dimensional drawing environment and a three-dimensional model-based definition environment;
receiving an annotation attached to a selected geometry on the displayed object in the two-dimensional drawing environment;
applying a two-dimensional view inverse transformation to the annotation attached to the selected geometry to produce a transformed version of the annotation; and
attaching the transformed version of the annotation to a geometry in a three-dimensional version of the object in the three-dimensional model-based definition environment.
